(19) United States
(12) Patent Application Publication
(10) Pub. No.: US 2024/0024925 A1
(43) Pub. Date: Jan. 25, 2024

(54) APPARATUS AND METHOD FOR MANUFACTURING DISPLAY DEVICE

(71) Applicant: SAMSUNG DISPLAY CO., LTD., Yongin-si (KR)

(72) Inventors: Jonghyup KIM, Yongin-si (KR); Yonghwan KIM, Yongin-si (KR); Haewook YANG, Yongin-si (KR)

(21) Appl. No.: 18/223,406

(22) Filed: Jul. 18, 2023

(30) Foreign Application Priority Data
Jul. 21, 2022 (KR) 10-2022-0090621

(51) Int. Cl. B08B 1/04; B08B 1/00

(52) U.S. Cl. CPC B08B 1/04; B08B 1/006

(57) ABSTRACT

An apparatus for manufacturing a display device, includes: a stage; and a pad including a first portion, where the first portion has a curvature identical to a first curvature of a first portion of a cover window of the display device extending in a first direction from a center area of the cover window.

This application claims priority to Korean Patent Application No. 10-2022-0090621, filed on Jul. 21, 2022, and all the benefits accruing therefrom under 35 U.S.C. § 119, the content of which in its entirety is herein incorporated by reference.

### BACKGROUND

### 1. Field

The disclosure relates to an apparatus and method for manufacturing a display device.

### 2. Description of the Related Art

Various types of display devices are being used based on mobility, and such display devices may include display panels configured to provide images and cover windows for protection of the display panels.

Recently, for flexible display devices, cover windows being at least partially curved are being developed.

### SUMMARY

In apparatuses for manufacturing display devices in the related art, curved portions of cover windows may not be properly cleaned.

One or more embodiments provide an apparatus and a method for manufacturing a display device, by which detergency of curved areas of a cover window may be improved and a cleaning time may be reduced. However, this is merely an embodiment, and the scope of the embodiments are not limited thereto.

According to one or more embodiments, an apparatus for manufacturing a display device includes a stage and a pad including a first portion, where the first portion has a curvature identical to a first curvature of a first area of a cover window of the display device extending in a first direction from a center area of the cover window.

According to an embodiment, the pad may further include a second portion, where the second portion may have a curvature identical to a second curvature of a second area of the cover window extending in a second direction crossing the first direction from the center area of the cover window.

According to an embodiment, the pad may have a first width in the first direction and a second width in the second direction.

According to an embodiment, the first width may be twice a radius of curvature of the first curvature of the first area of the cover window.

According to an embodiment, the cover window may have a first length in the second direction, and the second width may be identical to the first length.

According to an embodiment, the first curvature and the second curvature may be different from each other.

According to an embodiment, the apparatus may further include a pushing driver which moves the pad toward the cover window disposed on the stage.

According to the embodiment, the apparatus may further include a microfiber disposed between the pad and the stage.

According to one or more embodiment, an apparatus for manufacturing a display device includes a stage, a pad including a plurality of sawteeth arranged at a same interval toward outside of a cylinder-shaped main body having an axis hole, and an axis which rotates the pad.

According to an embodiment, on a cross-section of the pad in a first direction, a length of the sawteeth may be greater than a radius of a curvature of a first curvature of a first area of a cover window of the display device extending in a first direction from a center area of the cover window.

According to an embodiment, the axis may be inserted into the axis hole of the pad, and each of the axis hole and the axis may have a rectangular parallelepiped shape.

According to an embodiment, the sawtooth may include a third portion having a same curvature as a second curvature of a second area of the cover window extending in a second direction crossing the first direction from the center area of the cover window.

According to one or more embodiments, a method of manufacturing a display device includes: placing a cover window of the display device, on a stage, where the cover window includes a center area, a first area extending in a first direction from the center area and having a first curvature, and a second area extending in a second direction crossing the first direction from the center area and having a second curvature, bringing a pad and a microfiber into contact, bringing the microfiber to a surface of the cover window by moving down the pad toward the cover window, and cleaning the surface of the cover window by using the microfiber.

According to the embodiment, the method may further include before the bringing the pad and microfiber into contact, spraying ethanol to the microfiber.

According to the embodiment, the pad may include the first portion having a curvature identical to the first curvature.

According to the embodiment, the pad may further include a second portion having a curvature identical to the second curvature.

According to the embodiment, a width of the pad in the first direction may be twice a radius of curvature of the first curvature of the cover window.

According to the embodiment, a width of the pad in the second direction may be identical to a length of the cover window in the second direction.

According to the embodiment, the cleaning the surface of the cover window using the microfiber may include moving the stage in the first direction.

According to the embodiment, in the bringing the microfiber to the surface of the cover window by moving down the pad toward the cover window, the first portion and the first area may contact each other with the microfiber therebetween.

### BRIEF DESCRIPTION OF THE DRAWINGS

The above and other features of certain embodiments of the disclosure will be more apparent from the following description taken in conjunction with the accompanying drawings, in which:

FIG. 1 is a schematic cross-sectional view of a cleaning device according to an embodiment;

FIG. 2A is a schematic perspective view of a cover window according to an embodiment;

FIGS. 2B and 2C are schematic cross-sectional views of the cover window according to an embodiment;

FIG. 3A is a schematic perspective view of a pad according to an embodiment;

FIGS. 3B and 3C are schematic cross-sectional views of the pad according to an embodiment;

FIG. 4A is a schematic perspective view of a pad according to an embodiment;

FIGS. 4B and 4C are schematic cross-sectional views of the pad according to an embodiment;

FIG. 5 is a cross-sectional view of an axis according to an embodiment;

FIGS. 6A and 6B are a schematic perspective view and a cross-sectional view of a pad according to an embodiment;

FIGS. 7 to 11 are schematic cross-sectional views of a method of cleaning a cover window, according to an embodiment;

FIGS. 12 and 13 are schematic cross-sectional views of a method of cleaning a cover window, according to an embodiment; and

FIGS. 14 to 16 are schematic cross-sectional views of a method of cleaning a cover window, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

For convenience of explanation, sizes of components in the drawings may be exaggerated or reduced. For example, sizes and thicknesses of components shown in the drawings are arbitrarily shown for convenience of explanation, and therefore, the disclosure may not be limited to the drawing.

When an embodiment may be differently embodied, a specific order may be performed different from a described order. For example, two processes consequently described may be substantially simultaneously performed, and may be performed in an order opposite to the described order.

In the following embodiments, it will be understood that when a film, an area, or a component is referred to as being “connected” to another film, area, or component, the film, area, or component may be “directly” connected to the other film, area, or component or connected to the other film, area, or component with an intervening film, area, or component therebetween. For example, in the present specification, when a film, an area, or a component is referred to as being electrically connected to another film, area, or component, it will be understood that the film, area, or component may be electrically connected in a direct manner to the other film, area, or the component, and/or electrically connected in an indirect manner to the other film, area, or the component, with a film, area, or component therebetween.

The x axis, the y axis, and the z axis are not limited to three axes on an orthogonal coordinate system, and may be interpreted as broader meanings including the three axes on the orthogonal coordinate system. For example, the x axis, the y axis, and the x axis may be orthogonal to one another, but may also refer to different directions that are not orthogonal to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims

Hereinafter, embodiments will be described in detail with reference to the accompanying drawings, and in the descriptions with reference to the accompanying drawings, same reference numerals will be given to identical or corresponding components, and any repetitive detailed descriptions thereof will be omitted.

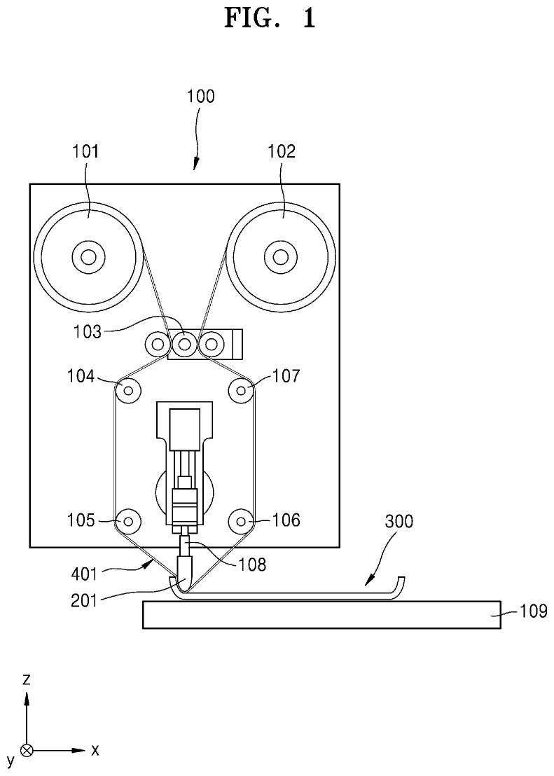

FIG. 1 is a schematic cross-sectional view of a cleaning device 100 according to an embodiment.

Referring to FIG. 1, an embodiment of the cleaning device 100 may include: a microfiber supply 101 and a microfiber retriever 102 respectively located at two sides of an upper portion of a cross-section (e.g., an xz cross-section) of the cleaning device 100 in the first direction (e.g., the x direction or −x direction), a motor 103 located in a middle portion of the cross-section, a plurality of rollers 104 to 107 (i.e., a first roller 104, a second roller 105, a third roller 106, and a fourth roller 107), a pushing driver 108, a pad 201, a stage 109, on which a cover window 300 is disposed, and a microfiber 401 in a lower portion of the cleaning device 100. The microfiber supply 101 and the microfiber retriever 102 may be located at the two sides of the upper portion of the cleaning device 100. The microfiber supply 101, which has the form of a roller, unrolls and supplies the microfiber 401, and the microfiber retriever 102, which also has the form of a roller, may roll and retrieve the microfiber 401. The motor 103, which is in the middle portion of the cleaning device 100, may maintain a tensile strength of the microfiber 401 until the microfiber 401 supplied by the microfiber supply 101 passes (or extends via) the first roller 104 and the second roller 105 and contacts the pad 201, and then passes the third roller 106 and the fourth roller 107 and is retrieved by the microfiber retriever 102, such that the cover window 300 may be cleaned. The microfiber 401 may pass the motor 103 and then pass the first roller 104, the second roller 105, the third roller 106, and the fourth roller 107. The microfiber 401 may pass the first roller 104 and the second roller 105 and contact the pad 201 and the cover window 300. The microfiber 401, which has passed the first roller 104 and the second roller 105, may pass between the pad 201 and the cover window 300. The microfiber 401 may contact the pad 201 and the cover window 300. The pushing driver 108 may be between the second roller 105 and the third roller 106. The pad 201 may be attached to the pushing driver 108. The microfiber 401 may be in contact with the pad 201 attached to the pushing driver 108. The pushing driver 108 may move the pad 201 toward the cover window 300 (e.g., downward or in a −z direction). As the microfiber 401 in contact with the pad 201 (or passing the pad 201) is brought into contact with the cover window 300, a surface of the cover window 300 may be cleaned. The cover window 300 and the stage 109 on which the cover window 300 is disposed may be under the pushing driver 108 and the pad 201. The stage 109 may be configured to support the cover window 300. The stage 109 may move the cover window 300 disposed thereon in the first direction (e.g., the x direction or −x direction), such that the microfiber 401 may clean the entire of the surface of the cover window 300.

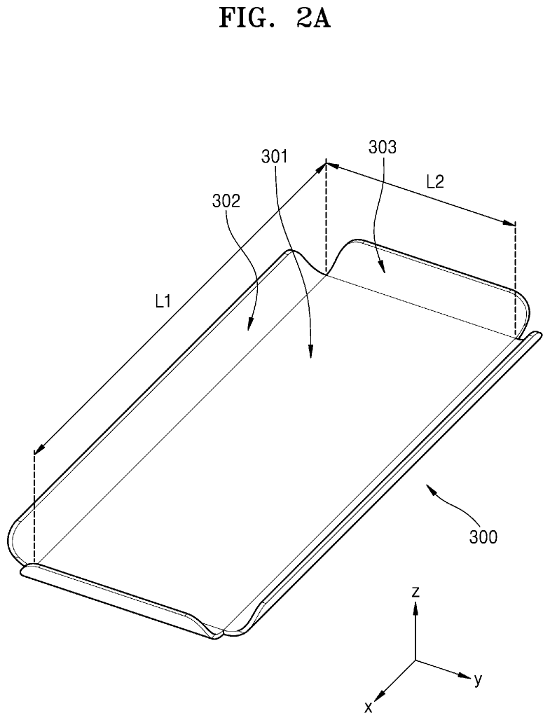

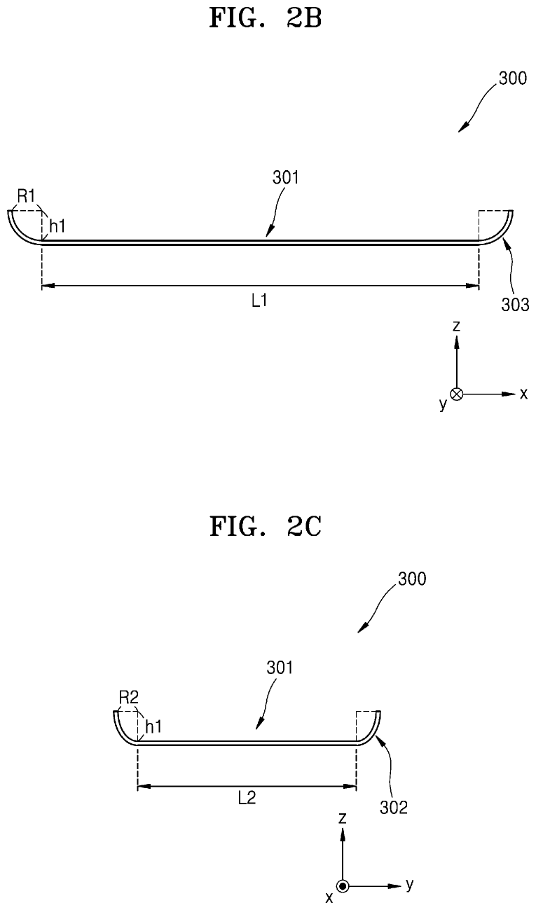

FIG. 2A is a schematic perspective view of the cover window 300 according to an embodiment, and FIGS. 2B and 2C are schematic cross-sectional views of the cover window 300 according to an embodiment.

Referring to FIGS. 2A to 2C, the cover window 300 may include a rigid material, for example, glass or plastic. The cover window 300 may protect, from external shock, a display panel configured to display images in display devices such as organic light-emitting display devices or liquid-crystal display devices, and may have a shape corresponding to a curved display device having a curved surface in at least a portion. The cover window 300 may include: a center area 301 including a plane surface and located in the center; a first area 303 extending in the first direction (e.g., the x direction or −x direction) from the center area 301 and having a first curvature; and a second area 302 extending in a second direction (e.g., a y direction or −y direction) from the center area 301 and having a second curvature.

The center area 301 is an area in the middle of the cover window 300 and may correspond to a largest portion. The center area 301 is in the middle of the cover window 300 on a cross-section (e.g., an xy cross-section) in the first direction (e.g., the x direction or −x direction), and may include a planar area having a rectangular shape. A length of the center area 301 in the first direction (e.g., the x direction or −x direction) may be defined as L1. A length of the center area 301 in the second direction (e. g., the y direction or −y direction) may be defined as L2. In other words, the center area 301 may have the form of a rectangle in which a length in the first direction (e.g. the x direction or −x direction) on the cross-section (e.g., the xy cross-section) in the first direction (e.g., the x direction or −x direction) is L1 and a length in the second direction (e.g., the y direction or −y direction) is L2. Although FIG. 2 illustrates an embodiment where the length L1 of the cover window 300 in the first direction (e.g., the x direction or −x direction) is greater than the length L2 of the cover window 300 in the second direction (e.g., the y direction or −y direction), the embodiments are not limited thereto. In an alternative embodiment, for example, the length of the cover window 300 in the second direction (e.g., the y direction or −y direction) may be greater than the length L1 of the cover window 300 in the first direction (e.g., the x direction or −x direction), or alternatively, the length L1 may be identical to (i.e., equal to or the same as) the length L2.

A length L1 of the center area 301 in the first direction (e.g., the x direction or −x direction) may be identical to the length L1 of the second area 302 of the cover window 300 in the first direction (e.g., the x direction or −x direction). A length L2 of the center area 301 in the second direction (e.g., the y direction or −y direction) may be identical to the length L2 of the first area 303 of the cover window 300 in the second direction (e.g., the y direction or −y direction).

The first area 303 may include an area extending in the first direction (e.g., the x direction or −x direction) from the center area 301 and having the first curvature. The first area 303 may be bent in the first direction (e.g., the x direction or −x direction) from the center area 301 in a first radius of curvature R1. The first area 303 may include an area extending in the first direction (e.g., the x direction or −x direction) from the center area 301 and being bent with the first curvature. The first area 303 may be defined as an area bent from the center area 301 on a cross-section (e.g., an xz cross-section) in the first direction (e.g., the x direction or −x direction). The first area 303 may extend in the second direction (e.g., the y direction or −y direction). In other words, the first area 303 may be not bent on the cross-section (e.g., an yz cross-section) in the second direction (e.g., the y direction or −y direction). The first area 303 may be connected to the center area 301 in the first direction (e.g., the x direction or −x direction). Although FIG. 2A illustrates an embodiment where the first area 303 extending in the x direction and being bent from the center area 301 and the first area 303 extending in the −x direction and being bent from the center area 301 have a same curvature as each other, but the embodiments are not limited thereto. In an alternative embodiment, for example, the first area 303 extending in the x direction and being bent from the center area 301 and the first area 303 extending in the −x direction and being bent from the center area 301 may have different curvatures from each other. However, the embodiments are not limited thereto.

The second area 302 may include an area extending in the second direction (e.g., the y direction or −y direction) from the center area 301 and having the second curvature. The second area 302 may be bent with a second radius of curvature R2 in the second direction (e.g., the y direction or −y direction) from the center area 301. The second area 302 may include an area extending in the second direction (e.g., the y direction or −y direction) from the center area 301 and being bent with the second curvature. The second area 302 may be defined as an area bent from the center area 301 on the cross-section (e.g., the yz cross-section) in the second direction (e.g., the y direction or −y direction). The second area 302 may extend in the first direction (e.g., the x direction or −x direction). The second area 302 may be not bent on a cross-section (e.g., the xz cross-section) orthogonal to the first direction (e.g., the x direction or the −x direction). Although FIG. 2C illustrates an embodiment where the second area 302 being bent and extending in the y direction from the center area 301 and the second area 302 being bent and extending in the −y direction from the center area 301 have a same curvature as each other, the embodiments are not limited thereto. In an alternative embodiment, for example, the second area 302 being bent and extending in the y direction from the center area 301 and the second area 302 being bent and extending in the −y direction may have different curvatures from each other. However, the embodiments are not limited thereto.

Although FIGS. 2A to 2C illustrate an embodiment where the first curvature of the first area 303 of the cover window 300 and the second curvature of the second area 302 of the cover window 300 are different from each other, the embodiments are not limited thereto. Alternatively, the first curvature of the first area 303 and the second curvature of the second area 302 may be identical to each other.

Referring to FIG. 2B, on the cross-section (e.g., the xz cross-section) of the cover window 300 in the first direction (e.g., the x direction or −x direction), areas having curvatures at two sides having curvatures may include the first area 303. The first area 303 may include the area extending in the first direction (e.g., the x direction or −x direction) from the center area 301 and having the first curvature. The first area 303 may include an area being bent with the first radius of curvature R1 in the first direction (e.g., the x direction or −x direction).

The first curvature may indicate a curvature in the first direction (e.g., the x direction or −x direction) of an edge (or a border) extending in the second direction (e.g., the y direction or −y direction) among four edges (or borders) of the cover window 300. In other words, the first curvature may indicate a curvature of two end portions (or end points) of the cover window 300 on the cross-section (e.g., the xz cross-section) of the cover window 300 in the first direction (e.g., the x direction or −x direction). The first radius of curvature R1 may indicate a radius of curvature of a curvature in the first direction of the edge (or border) extending in the second direction (e.g., the y direction or −y direction) among the four edges (or borders) of the cover window 300. In other words, the first radius of curvature R1 may indicate a radius of curvature of a curvature of the two end portions (or end points) of the cover window 300 on the cross-section (e.g., the xz cross-section) of the cover window 300 in the first direction (e.g., the x direction or −x direction).

A height h1 of the cover window 300 may be a length of the cover window 300 in a third direction (e.g., a z direction or −z direction). The height h1 of the cover window 300 may indicate a length in the third direction (e.g., the z direction) from a point at which the first area 303 of the center area 301 starts on the cross-section (e.g. the xz cross-section) of the cover window 300 in the first direction (e.g., the x direction or −x direction) to a border (or a corner) of the cover window 300. The height h1 of the cover window 300 may be identical to the first radius of curvature R1. The height h1 of the cover window 300 may include the first radius of curvature R1. In such an embodiment, on the cross-section (e.g., the xz cross-section) of the cover window 300 in the first direction (e.g., the x direction or −x direction), the first area 303 may have the form of an arc of a circle having the first radius of curvature R1 (or the height h1 of the cover window 300) as a radius. Although FIG. 2B illustrates an embodiment where the first radius of curvature R1 and the height h1 of the cover window 300 are identical to each other, the embodiments are not limited thereto. Alternatively, the first radius of curvature R1 may be different from the height h1 of the cover window 300. In an embodiment where the first radius of curvature R1 and the height h1 of the cover window 300 are different from each other, on the cross-section (e.g., the xz cross-section) of the cover window 300 in the first direction (e.g., the x direction or −x direction), the first area 303 may have the form of an arc of an ellipse.

Referring to FIG. 2C, FIG. 2C shows a cross-section (e.g., an yz cross-section) of the cover window 300 in the second direction (e.g., the y direction or −y direction). On the cross-section (e.g., the yz cross-section) of the cover window 300 in the second direction (e.g., the y direction or −y direction), areas having curvature at two sides may include the second area 302. The second area 302 may include an area extending in the second direction (e.g., the y direction or −y direction) from the center area 301 and having the second curvature. The second area 302 may include an area being bent in the second direction (e.g., the y direction or −y direction) with the second radius of curvature R2.

The second curvature may indicate a curvature in the second direction (e.g., the y direction or −y direction) of an edge (or border) extending in the first direction among the four edges (or borders) of the cover window 300. In other words, the second curvature may indicate a curvature of two end portions (or end points) of the cover window 300 on the cross-section (e.g., the yz cross-section) of the cover window 300 in the second direction (e.g., the y direction or −y direction). The second radius of curvature R2 may indicate a radius of a curvature in the second direction of the edge (or border) extending in the first direction (e.g., the x direction or −x direction) among the four edges (or borders) of the cover window 300. In other words, the second radius of curvature R2 may indicate a radius of a curvature of the two end portions (or end points) of the cover window 300 on the cross-section (e.g., the yz cross-section) of the cover window 300 in the second direction (e.g., the y direction or −y direction).

The height h1 of the cover window 300 may be a length of the cover window 300 in the third direction (e.g., the z direction or −z direction). The height L1 of the cover window 300 may indicate a length in the third direction (e.g., the z direction or −z direction) from a point at which the second area 302 of the center area 301 starts to the border (or edge) of the cover window 300 on the cross-section (e.g., the yz cross-section) of the cover window 300 in the second direction (e.g., the y direction or −y direction). The height h1 of the cover window 300 and a length of the second radius of curvature R2 may be different from each other. In an embodiment where the second radius of curvature R2 and the height h1 of the cover window 300 are different from each other, on the cross-section (e.g., the yz cross-section) in the second direction (e.g., the y direction or −y direction) of the cover window 300, the second area 302 may have the form of an arc of an ellipse. Although FIG. 2C illustrates an embodiment where the second radius of curvature R2 and the height h1 of the cover window 300 are different from each other, the embodiments are not limited thereto. Alternatively, the second radius of curvature R2 and the height h1 of the cover window 300 may be identical to each other. The height h1 of the cover window 300 may include the second radius of curvature R2. In an embodiment, on the cross-section (e.g., the yz cross-section) of the second area 302 in the second direction (e.g., the y direction or −y direction), the second area 302 may have the form of an arc of a circle having the second radius of curvature R2 (or the height h1 of the cover window 300) as a radius.

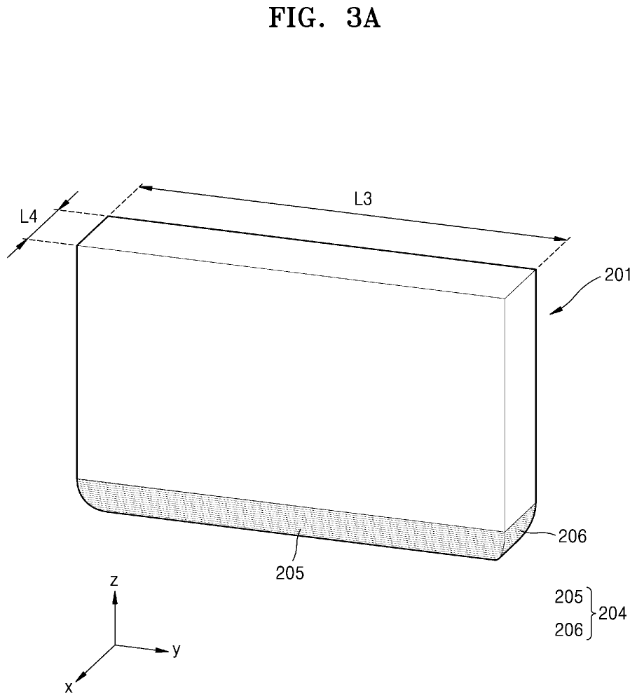

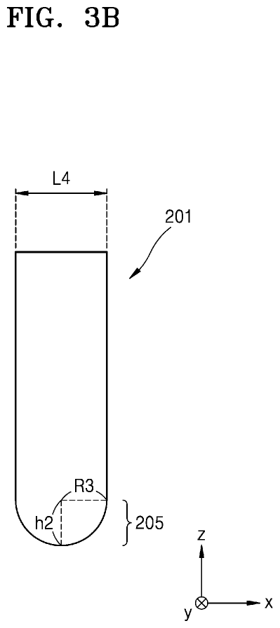

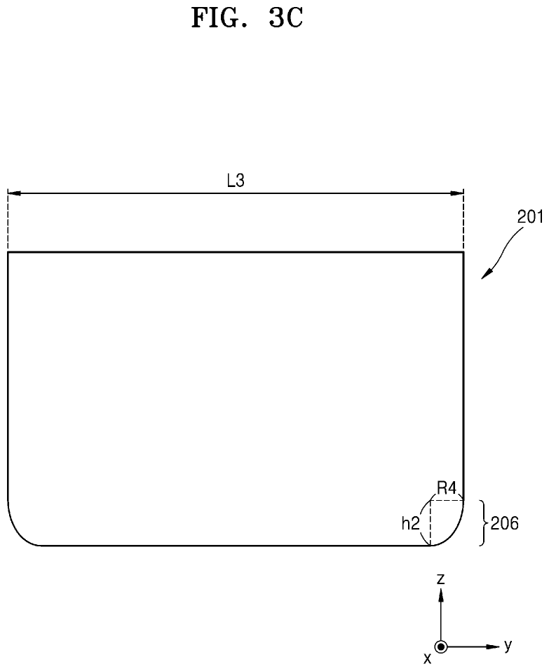

FIG. 3A is a schematic perspective view of the pad 201 according to an embodiment, and FIGS. 3B and 3C are schematic cross-sectional views of the pad 201 according to an embodiment. FIG. 3B schematically illustrates the cross-section (e.g., the xz cross-section) of the pad 201 in the first direction (e.g., the x direction or −x direction), and FIG. 3B schematically illustrates the cross-section (e.g., the yz cross-section) of the pad 201 in the second direction (e.g., the y direction or −y direction).

Referring to FIGS. 3A to 3C, in an embodiment, the pad 201 may be under the pushing driver 108 (see FIG. 1), and may be moved toward the cover window 300 (see FIG. 1) (e.g., downward or in the −z direction) by the pushing driver 108. The microfiber 401 that has passed the first roller 104 (see FIG. 1) and the second roller 105 (see FIG. 1) may pass a girth of the pad 201. The pad 201 may bring the microfiber 401 into contact with the cover window 300, such that the cover window 300 may be cleaned. In an embodiment, a material of the pad 201 may include silicon having elasticity. Alternatively, the pad 201 may include urethane, wood, plastics, and the like having elasticity similar to that of silicon. Alternatively, the pad 201 may include a metal that does not have elasticity. In an embodiment, for example, the pad 201 may include a metal that does not react with ethanol, such as, aluminum, urethane, or the like.

The pad 201 may include a rectangular parallelepiped shape as a main body, and among lateral surfaces of the main body that is a rectangular parallelepiped, an area 204 located in a downward direction (e.g., the −z direction) (hereinafter will be referred to as a bent area 204) may be bent in the first direction (e.g., the x direction or −x direction) and the second direction (e.g., the y direction or −y direction). In the bent area 204 in a lower portion of the pad 201, a first portion 205 may have a third curvature in the first direction (e.g., the x direction or −x direction). In the bent area 204 in the lower portion of the pad 201, a second portion 206 may have a fourth curvature in the second direction (e.g., the y direction or −y direction). A length of the pad 201 in the first direction (e.g., the x direction or −x direction) may be defined as L4. A length of the pad 201 in the second direction (e.g., the y direction or −y direction) may be defined as L3.

In the main body of the rectangular parallelepiped of the pad 201, the bent area 204 bent in the first direction (e.g., the x direction or −x direction) and the second direction (e.g., the y direction or −y direction) may include areas matching (or configured to contact) the first direction and the second area 302 of the cover window 300 with the microfiber 401 therebetween. The first portion 205 of the pad 201 may match (or contact) the first area 303 of the cover window 300 with the microfiber 401 therebetween. The second portion 206 of the pad 201 may match (or contact) the second area 302 of the cover window 300 with the microfiber 401 between.

In the bent area 204 in the lower portion of the pad 201, the first portion 205 may have the third curvature on the cross-section (e.g., the xz cross-section) of the pad 201 in the first direction (e.g., the x direction or −x direction). The third curvature may include a curvature of a point at which the first portion 205 starts in an edge (or a border) of the pad 201 in the third direction (e.g., the z direction or −z direction) on the cross-section (e.g., the xz cross-section) of the pad 201 in the first direction (e.g., the x direction or −x direction). The third radius of curvature R3 may include a radius of curvature of a curvature of the point at which the first portion 205 starts in an edge (or a border) of the cover window 300 in the third direction (e.g., the z direction or −z direction) on the cross-section (e.g., the xz plane) of the cover window 300 in the first direction (e.g., the x direction or −x direction).

In an embodiment, the first portion 205 of the pad 201 and the first area 303 of the cover window 300 may have a same curvature as each other. In an embodiment, for example, the third curvature, which is the curvature of the first portion 205 of the pad 201, and the first curvature, which is the curvature of the first area 303 of the cover window 300, may be identical to each other. In such an embodiment, a third radius of curvature R3 of the first portion 205 of the pad 201 and the first radius of curvature R1 of the first area 303 of the cover window 300 may be identical to each other. However, the embodiments are not limited thereto. The first portion 205 of the pad 201 and the first area 303 of the cover window 300 may have different curvatures from each other. In an embodiment where the first portion 205 of the pad 201 and the first area 303 of the cover window 300 have a same curvature as each other, the first portion 205 of the pad 201 may match the first area 303 of the cover window 300. In addition, an adhesion between the first portion 205 of the pad 201 and the first area 303 of the cover window 300 may be improved.

The height h2 of the bent area 204 of the pad 201 may be a length from the point at which the first portion 205 starts in the edge (or the border) in the third direction (e.g., the z direction or −z direction) to an end point of the pad 201 in the third direction (e.g., the −z direction) on the cross-section (e.g., the xz plane) of the pad 201 in the first direction (e.g., the x direction or −x direction). The height h2 of the bent area 204 of the pad 201 may be identical to a length of the height h1 of the cover window 300. The height h2 of the bent area 204 of the pad 201 (or the height h1 of the cover window 300) may be identical to the third radius of curvature R3 of the pad 201. In such an embodiment, on the cross-section (e.g., the xz plane) of the pad 201 in the first direction (e.g., the x direction or −x direction), the first portion 205 may have the form of an arc having the third radius of curvature R3 (or the height h2 of the bent area 204 of the pad 201) as a radius. Although FIG. 3B illustrates an embodiment where the third radius of curvature R3 and the height h2 of the bent area 204 of the pad 201 (or the height h1 of the cover window 300) are identical to each other, the embodiments are not limited thereto). Alternatively, the third radius of curvature R3 of the pad 201 and the height h2 of the bent area 204 of the pad 201 (or the height h1 of the cover window 300) may be different from each other. In such an embodiment, on the cross-section (e.g., the xz plane) of the pad 201 in the first direction (e.g., the x direction or −x direction), the first portion 205 may have the form of an arc of an ellipse.

The length of the pad 201 in the first direction (e.g., the x direction or −x direction) may be L4. The first portion 205 of the pad 201 may match (or contact) the first area 303 of the cover window 300. The length L4 of the pad 201 in the first direction (e.g., the x direction or −x direction) may be about twice the first radius of curvature R1 of the first area 303 of the cover window 300. In an embodiment where the first portion 205 of the pad 201 and the first area 303 of the cover window 300 have a same curvature as each other and the length L4 of the pad 201 in the first direction (e.g., the x direction or −x direction) is about twice the first radius of curvature R1 of the first area 303 of the cover window 300, an adhesion between the pad 201 and the cover window 300 may be improved, and as the cover window 300 may be cleaned at once using one pad 201, a cleaning time of the cover window 300 may be reduced. In such an embodiment, the first portion 205 of the pad 201 and the first area 303 of the cover window 300 may match each other.

Although FIG. 3A illustrates an embodiment where a radius of curvature of a portion bent in the x direction in the first portion 205 of the pad 201 is identical to a radius of curvature of a portion bent in the −x direction in the first portion 205, the embodiments are not limited thereto. Alternatively, the radius of curvature of the portion bent in the x direction in the first portion 205 and the radius of curvature of the portion bent in the −x direction in the first portion 205 may be different from each other. In such an embodiment, the length L4 of the pad 201 in the first direction (e.g., the x direction or −x direction) may include a sum of the radius of curvature of the portion bent in the x direction in the first portion 205 and the radius of curvature of the portion bent in the −x direction in the first portion 205.

In the bent area 204 of the lower portion of the pad 201, the second portion 206 may have the fourth curvature on the cross-section (e.g., the yz cross-section) of the pad 201 in the second direction (e.g., the y direction or −y direction). The fourth curvature may include a curvature of a point at which the second portion 206 starts in an edge (or a border) of the pad 201 in the third direction (e.g., the z direction or −z direction) on the cross-section (e.g., the yz cross-section) of the pad 201 in the second direction (e.g., the y direction or −y direction). The fourth radius of curvature R4 may include a radius of curvature of a curvature of the point at which the second portion 206 starts in an edge (or a border) of the cover window 300 in the third direction (e.g., the z direction or −z direction) on the cross-section (e.g., the yz cross-section) of the cover window 300 in the second direction (e.g., the y direction or −y direction).

In an embodiment, the second curvature of the second area 302 of the cover window 300 and the fourth curvature of the second portion 206 of the pad 201 may be identical to each other. In such an embodiment, the fourth radius of curvature R4 of the pad and the second radius of curvature R2 of the cover window 300 may be identical to each other. However, the embodiments are not limited thereto. Alternatively, the second curvature of the second area 302 of the cover window 300 and the fourth curvature of the second portion 206 of the pad 201 may be different from each other.

As the second curvature of the second area 302 of the cover window 300 and the fourth curvature of the second portion 206 of the pad 201 are identical to each other, the second area 302 of the cover window 300 and the second portion 206 of the pad 201 may match each other. In addition, an adhesion between the second area 302 of the cover window 300 and the second portion 206 of the pad 201 may be improved, and as the cover window 300 may be cleaned at once using one pad 201, a cleaning time of the cover window 300 may be reduced.

The height h2 of the bent area 204 of the pad 201 may be a length from the point at which the second portion 206 starts in the edge (or the border) in the third direction (e.g., the z direction or −z direction) to an end point of the pad 201 in the third direction (e.g., the −z direction) on the cross-section (e.g., the yz cross-section) of the pad 201 in the second direction (e.g., the y direction or −y direction). In an embodiment, the height h2 of the bent area 204 of the pad 201 may be identical to the length of the height h1 of the cover window 300. Alternatively, the fourth radius of curvature R4 of the pad 201 and the height h2 of the bent area 204 of the pad 201 (or the height h1 of the cover window 300) may be different from each other. In such an embodiment, on the cross-section (e.g., the yz cross-section) of the pad 201 in the second direction (e.g., the y direction or −y direction), the second portion 206 may have the form of an arc of an ellipse. Although FIG. 3C illustrates an embodiment where the fourth radius of curvature R4 of the pad 201 and the height h2 of the bent area 204 of the pad 201 (or the height h1 of the cover window 300) are different from each other, the embodiments are not limited thereto. Alternatively, the fourth radius of curvature of the pad 201 and the height h2 of the bent area 204 of the pad 201 (or the height h1 of the cover window 300) may be identical to each other. In such an embodiment, on the cross-section (e.g., the yz cross-section) of the pad 201 in the second direction (e.g., the y direction or −y direction), the second portion 206 may have the form of an arc of a circle having the fourth radius of curvature R4 as a radius.

A length of the pad 201 in the second direction (e.g., the y direction or −y direction) may be L3. The length L3 of the pad 201 in the second direction (e.g., the y direction or −y direction) may be identical to the length L2 of the cover window 300 in the second direction (e.g., the y direction or −y direction). In such an embodiment where the length L3 of the pad 201 in the second direction (e.g., the y direction or −y direction) is identical to the length L2 of the cover window 300 in the second direction (e.g., the y direction or −y direction), the second portion 206 of the pad 201 and the second area 302 of the cover window 300 may match each other.

In an embodiment, the third curvature of the first portion 205 of the pad 201 may be identical to the first curvature of the first area 303 of the cover window 300, the fourth curvature of the second portion 206 of the pad 201 may be identical to the second curvature of the second area 302 of the cover window 300, and the length L3 of the pad 201 in the second direction (e.g., the y direction or −y direction) may be identical to the length L2 of the cover window 300 in the second direction (e.g., the y direction or −y direction). In addition, the length L4 of the pad 201 in the first direction (e.g., the x direction or −x direction) may be about twice the first radius of curvature R1 of the first area 303 of the cover window 300. In such an embodiment, the pad 201 and the cover window 300 may match each other, the adhesion between the pad 201 and the cover window 300 may be improved, and as the cover window 300 may be cleaned at once using one pad 201, a cleaning time of the cover window 300 may be reduced.

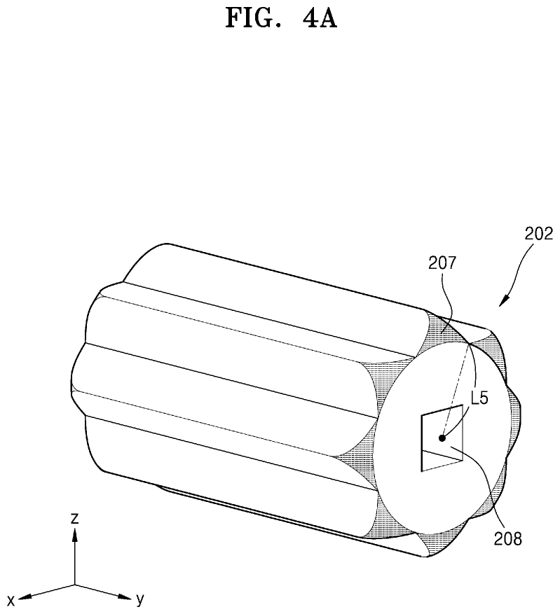

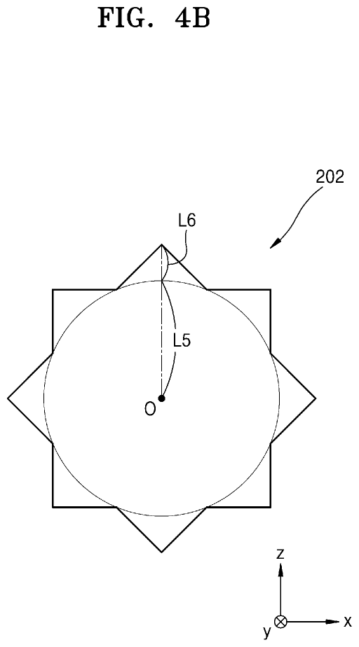

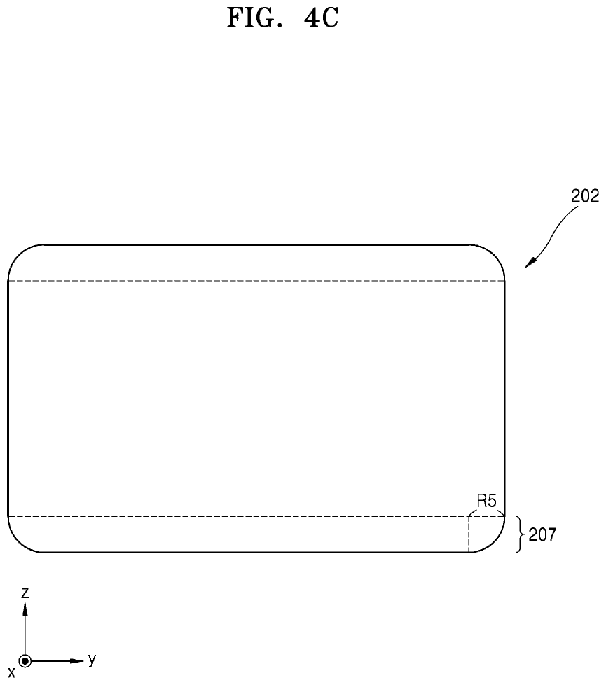

FIG. 4A is a schematic perspective view of a pad according to an embodiment, and FIGS. 4B and 4C are schematic cross-sectional views of the pad according to an embodiment. FIG. 4B schematically illustrates the cross-section (e.g., the xz cross-section of a pad 202 in the first direction (e.g., the x direction or −x direction), and FIG. 4C schematically illustrates the cross-section (e.g., the yz cross-section) of the pad 202 in the second direction (e.g., the y direction or −y direction).

Referring to FIGS. 4A to 4C, in an embodiment, the pad 202 may include a plurality of sawteeth arranged at a same interval toward outside a cylinder-shaped main body including an axis hole 208. A shape of the pad 202 may include a shape having the plurality of sawteeth on a rotatable axis. The axis hole 208 may have a rectangular parallelepiped shape. In an embodiment, the pad 202 may include silicon material having elasticity and extraordinary chemical resistance, but the embodiments are not limited thereto. A bent portion 207 that is bent in the second direction (e.g., the y direction or −y direction) may be in a sawtooth of the pad 202. In the sawtooth of the pad 202, the bent portion 207 bent in the second direction (e.g., the y direction or −y direction) may have a fifth curvature in the second direction (e.g., the y direction or −y direction). Details thereof will be described later.

A length of a radius of a circle in the cross-section (e.g., the xz cross-section) of the pad 202 in the first direction (e.g., the x direction or −x direction) may be defined as L5. A length L6 of the sawtooth may include a length L6 obtained by subtracting the length L5 of the radius of the circle from a length between a center O of the circle and a portion at which the sawtooth protrudes to a greatest degree.

Although FIG. 4B illustrates an embodiment where each sawtooth has a triangle shape on the cross-section (e.g., the xz cross-section) of the pad 202 in the first direction (e.g., the x direction or −x direction), the embodiments are not limited thereto. Alternatively, although not shown, a shape of the sawtooth may include various shapes such as a trapezoid shape or a round shape.

Although FIG. 4B illustrates an embodiment where eight sawteeth are provided, the embodiments are not limited thereto. In an alternative embodiment, for example, the number of the sawteeth may be four, six, ten or more.

The pad 202 having the sawtooth shape may rotate when the microfiber 401 is brought into contact with the cover window 300. For rotation of the pad 202, it is desired that a length L6 of a sawtooth of the pad 202 is greater than the first radius of curvature R1 of the first area 303 of the cover window 300. In addition, for rotation of the pad 202, it is required that the length L5 of the radius of an inner circle of the cross-section (e.g., the xz cross-section) of the pad 202 in the first direction (e.g., the x direction or −x direction) is greater than the length of the first radius of curvature R1.

In the cross-section (e.g., the yz cross-section) of the pad 202, four edges may be bent having a rectangular shape as a main body. In the pad 202, the bent portion 207 in the sawtooth of the pad 202 and the second area 302 of the cover window 300 may match (or contact) each other with the microfiber 401 between. The curvature in the second direction (e.g., the y direction or −y direction) of the bent portion 207 in the sawtooth of the pad 202 may include the fifth curvature. The fifth curvature of the pad 202 may indicate a curvature in the second direction at a point which the bent portion 207 of the pad 202 starts on a line (or an edge) in the third direction (e.g., the z direction or −z direction) on the cross-section (e.g., the yz cross-section) of the pad 202 in the second direction (e.g., the y direction or −y direction). On the cross-section (e.g., the yz cross-section) of the pad 202 in the second direction (e.g., the y direction or −y direction), a radius of curvature of the curvature in the second direction (e.g., the y direction or −y direction) of the point at which the bent portion 207 of the pad 202 starts on the line (or the edge) in the third direction (e.g., the z direction or −z direction) may include the fifth radius of curvature R5. In an embodiment, the fifth radius of curvature R5 of the bent portion 207 in the sawtooth of the pad 202 and the second curvature of the second area 302 of the cover window 300 may be identical to each other. In such an embodiment, the fifth radius of curvature R5 of the pad 202 and the second radius of curvature R2 of the cover window 300 may be identical to each other. However, the embodiments are not limited thereto. In an embodiment where the fifth curvature of the bent portion 207 of the pad 202 and the second curvature of the second area 302 of the cover window 300 are identical to each other, the pad 202 and the cover window 300 may match each other, and an adhesion between the pad 202 and the cover window 300 may be improved.

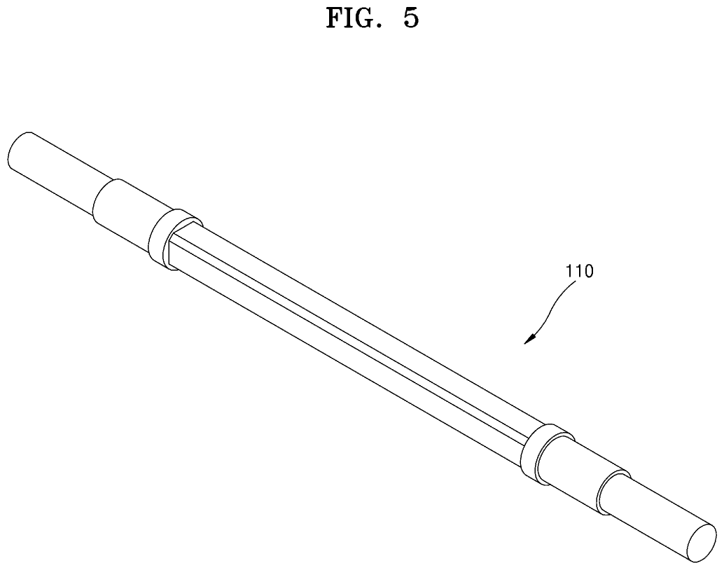

FIG. 5 is a schematic perspective view of an axis 110 according to an embodiment. More particularly, FIG. 5 is a schematic perspective view of the axis 110 inserted into the axis hole 208 (see FIG. 4A) of the pad 202 (see FIG. 4A).

Referring to FIG. 5B, in an embodiment, the pad 202 having the sawtooth shape may rotate when the microfiber 401 cleans the cover window 300. For rotation of the pad 202, the axis 110 may be in the axis hole 208 of the pad 202. In an embodiment, a portion of the axis 110 inserted into the pad 202 may have a rectangular parallelepiped shape to prevent sliding of the axis 110 during rotation of the pad 202. In such an embodiment, step structures may be defined at four corners of lateral surfaces of the rectangular parallelepiped to prevent movement of the pad 202.

For rotation of the pad 202, an additional motor may be provided in the pad 202 in addition to the motor 103 (see FIG. 1). Due to the additional motor provided in the pad 202, a force for rotation of the pad 202 may increase. However, the embodiments are not limited thereto.

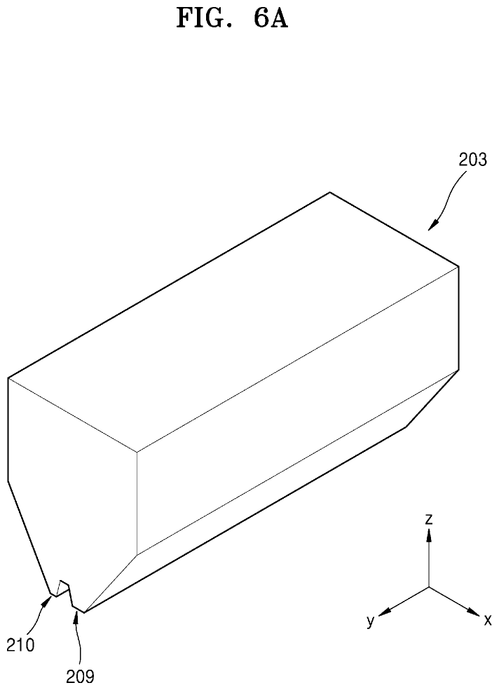

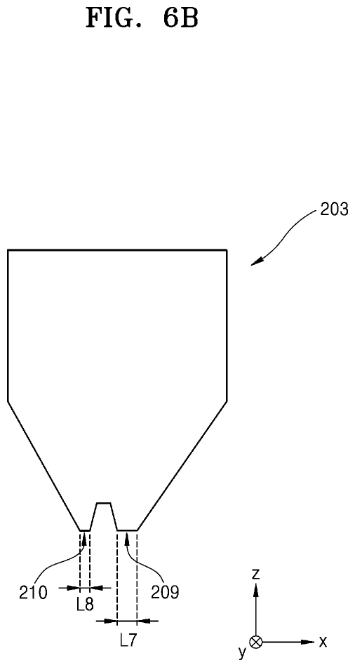

FIG. 6A is a schematic perspective view of a pad according to an embodiment, and FIGS. 6B and 6C are schematic cross-sectional views of the pad according to an embodiment.

Referring to FIGS. 6A and 6B, in an embodiment, a lower portion of a pad 203 may have a trigonal prism as a main body, and two trapezoids may be at vertices close to the cover window 300 (see FIG. 2A) (e.g., toward the −z direction) on the cross-section (e.g., the xz cross-section) in the first direction (e.g., the x direction or −x direction). When the microfiber 401 (see FIG. 1) passing the pad 203 cleans the cover window 300, an angle of the pad 203 in the first area 303 (see FIG. 2A) of the cover window 300 may be changed. As the angle of the pad 203 is changed, the microfiber 401 passing a girth of the pad 203 may be in contact with the first area 303 of the cover window 300. In such an embodiment where the angle of the pad 203 changes, a lower portion of the pad 203 on the cross-section (e.g., the xz cross-section) in the first direction (e.g., the x direction or −x direction) may have a triangle shape to avoid contact with the cover window 300.

Two trapezoids in the lower portion (e.g., in the −z direction) of the pad 203 may be apart from each other in the first direction (e.g., the x direction or −x direction). On the cross-section (e.g., the xz cross-section) of the pad 203 in the first direction (e.g., the x direction or −x direction), a flat portion of a lower portion of a trapezoid in the + direction between the two trapezoids may be defined as a third portion 209. On the cross-section (e.g., the xz cross-section) of the pad 203 in the first direction (e.g., the x direction or −x direction), a flat portion of a lower portion of a trapezoid in the −x direction (or on the left) between the two trapezoids may be defined as a fourth portion 210.

The microfiber 401 may pass girths of the two trapezoids at the vertex of the pad 203. The microfiber 401 passing a girth of the third portion 209 may be primarily in contact with the cover window 300. The microfiber 401 passing a girth of the fourth portion 210 may be secondarily in contact with the cover window 300. The microfiber 401 passing the third portion 209 and the fourth portion 210 of the pad 203 may be in contact with the first area 303 of the cover window 300 twice. Due to increase in the number of contacts between the microfiber 401 and the cover window 300, foreign materials on the surface of the cover window 300 may be better removed. After the microfiber 401 passing the third portion 209 of the pad 203 primarily cleans the cover window 300, a portion that has been insufficiently cleaned is secondarily cleaned by the microfiber 401 passing the fourth portion 210, and therefore, foreign materials on the surface of the cover window 300 may be better removed.

A length of the third portion 209 may be defined as L7. A length of the fourth portion 210 may be defined as L8. In an embodiment, the length L7 of the third portion 209 may be identical to the length L8 of the fourth portion 210. Alternatively, the length L7 of the third portion 209 may be greater than the length L8 of the fourth portion 210. The length L7 of the third portion 209 may be about 3 millimeters (mm) or less. The length L7 of the third portion 209 may be equal to or greater than the length L8 of the fourth portion 210, and may be about 3 mm or less.

A material of the pad 203 may include silicon having elasticity and extraordinary chemical resistance. However, the embodiments are not limited thereto. Although FIG. 6B illustrates an embodiment where two trapezoids are defined (e.g., provided or formed) in the lower portion of the pad 203 in the cross-section (e.g., the xz cross-section) of the pad 203 in the first direction (e.g., the x direction or −x direction), the embodiments are not limited thereto. Alternatively, three, four, five or more trapezoids, as well as two trapezoids, may be defined in the lower portion of the pad 203.

Although FIG. 6B illustrates an embodiment where the trapezoids are defined in the lower portion of the pad 203 in the cross-section (e.g., the xz cross-section) of the pad 203 in the first direction (e.g., the x direction or −x direction), the embodiments are not limited thereto. Alternatively, triangles may be defined in the lower portion of the cross-section (e.g., the xz cross-section) of the pad 203 in the first direction (e.g., the x direction or −x direction). The number of triangles may be two, three, four or more. In the cross-section (e.g., the xz cross-section) of the pad 203 in the first direction (e.g., the x direction or −x direction). In such an embodiment where the lower portion of the pad 203 has a triangle shape instead of a trapezoid shape, as the pad 203 may be bent, it may be desired to increase the hardness of the pad 203.

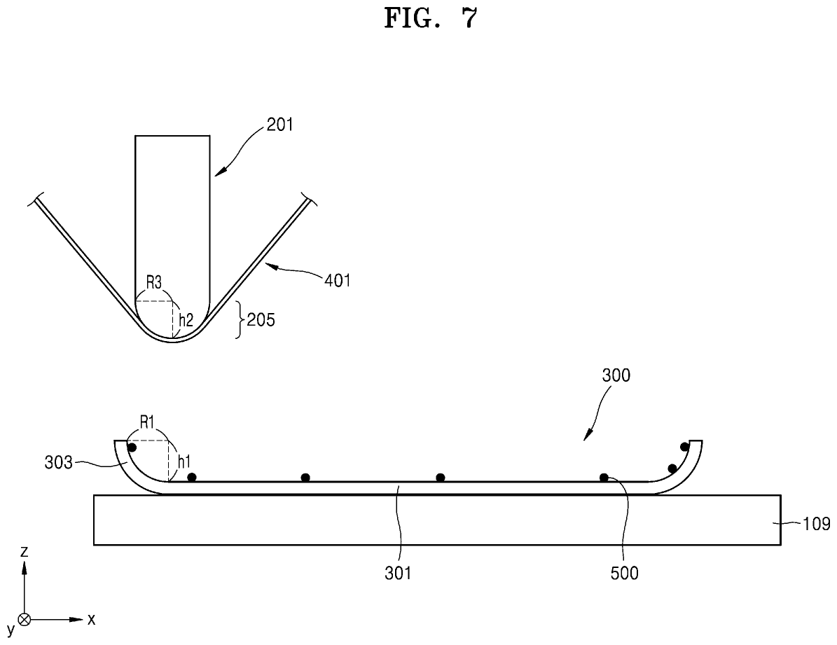

FIGS. 7 to 11 are schematic cross-sectional views showing a method of cleaning the cover window 300 according to an embodiment. More particularly, FIGS. 7 to 11 are schematic cross-sectional views showing a method of cleaning the cover window 300 by using the cleaning device of the cover window 300 including the pad shown in FIGS. 4A to 4C.

Referring to FIGS. 7 to 11, after placing the cover window 300 on the stage 109, where the cover window 300 includes the center area 301, the first area 303 extending in the first direction (e.g., the x direction or −x direction) from the center area 301 and having the first curvature, and the second area 302 extending in the second direction (e.g., the y direction or −y direction) crossing the first direction (e.g., the x direction or the −x direction) from the center area 301 and having the second curvature, the method of cleaning the cover window 300 may include: bringing the pad 201 and the microfiber 401 into contact with each other, where the pad 201 includes the first portion 205 having a same curvature as the first curvature; bringing the microfiber 401 into contact with the surface of the cover window 300 by moving down the pad 201 toward the cover window 300; and cleaning the surface of the cover window 300 by using the microfiber 401.

Referring to FIG. 7, the first portion 205 of the pad 201 may have the third curvature. The first portion 205 of the pad 201 may be bent with the third radius of curvature R3. The height of the bent area 204 of the pad 201 may be h2. The height h2 of the bent area 204 of the pad 201 may include a length from the point at which the first portion 205 starts in the edge (or the border) in the third direction (e.g., the z direction or −z direction) to an end point of the pad 201 in the third direction (e.g., the −z direction) on the cross-section (e.g., the xz plane) of the pad 201 in the first direction (e.g., the x direction or −x direction).

An area of the cover window 300 bending while extending in the first direction (e.g., the x direction or −x direction) from the center area 301 of the cover window 300 may include the first area 303. The first area 303 may include an area being bent in the first direction (e.g., the x direction or −x direction) with the first curvature. The first area 303 may include the area being bent in the first direction (e.g., the x direction or −x direction) with the first radius of curvature R1. The height of the cover window 300 may be h1. The height h1 of the cover window 300 may indicate a length in the third direction (e.g., the z direction) from a point at which the first area 303 starts in the center area 301 to a border (or an edge) of the cover window 300 on the cross-section (e.g., the xz cross-section) of the cover window 300 in the first direction (e.g., the x direction or −x direction).

The method may further include spraying ethanol to the microfiber 401 before bringing the pad 201 and the microfiber 401 into contact with each other.

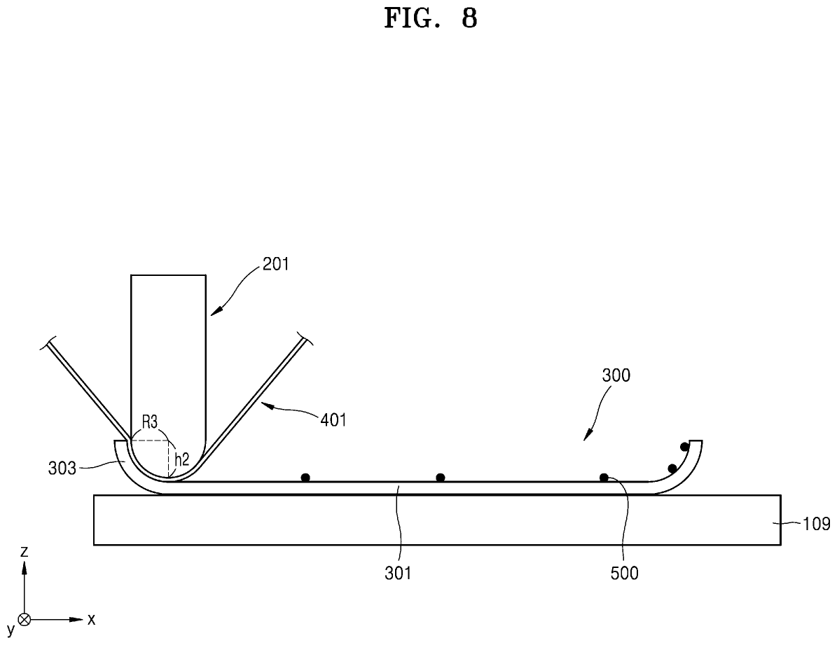

FIG. 8 is a schematic cross-sectional view of a process of bringing the microfiber 401 into contact with the surface of the cover window 300 by moving down the pad 201 toward the cover window 300 (e.g., in the −z direction). The third radius of curvature R3 of the first portion 205 of the pad 201 and the first radius of curvature R1 of the first area 303 of the cover window 300 may be identical to each other. The height h1 of the cover window 300 may be identical to the height h2 of the bent area 204 of the pad 201. Accordingly, the first portion 205 of the pad 201 and the first area 303 of the cover window 300 may match each other with the microfiber 401 therebetween.

Although FIG. 8 illustrates an embodiment where the height h2 of the bent area 204 of the pad 201 (or the height h1 of the cover window 300) and the third radius of curvature R3 of the first portion 205 (see FIG. 7) of the pad 201 (or the first radius of curvature R1 of the first area 303 of the cover window 300) are identical to each other, the embodiments are not limited thereto.

As the first portion 205 of the pad 201 and the first area 303 of the cover window 300 are in contact with each other with the microfiber 401 therebetween, foreign materials 500 on a surface of the first area 303 of the cover window 300 may contact the microfiber 401 and then be removed.

Although not shown in FIG. 8, the second portion 206 of the pad 201 and the second area 302 of the cover window 300 may match each other with the microfiber 401 therebetween. In other words, the fourth curvature of the second portion 206 (see FIG. 3A) of the pad 201 and the second curvature of the second area 302 of the cover window 300 may be identical to each other. The fourth radius of curvature R4 of the second portion 206 of the pad 201 and the second radius of curvature R2 of the second area 302 of the cover window 300 may be identical to each other.

In an embodiment where the first portion 205 of the pad 201 matches the first area 303 of the cover window 300 with the microfiber 401 therebetween, the width L4 (see FIG. 3A) of the pad 201 in the first direction (e.g., the x direction or −x direction) may be twice the first radius of curvature R1 of the cover window 300 (or the third radius of curvature R3) of the pad 201). In an embodiment where the second portion 206 (see FIG. 3A) of the pad matches the second area 302 of the cover window 300 with the microfiber 401 therebetween, the width L3 (see FIG. 3A) of the pad 201 in the second direction (e.g., the y direction or −y direction) may be identical to the length L2 (see FIG. 2A) of the cover window 300 in the second direction (e.g., the y direction or −y direction).

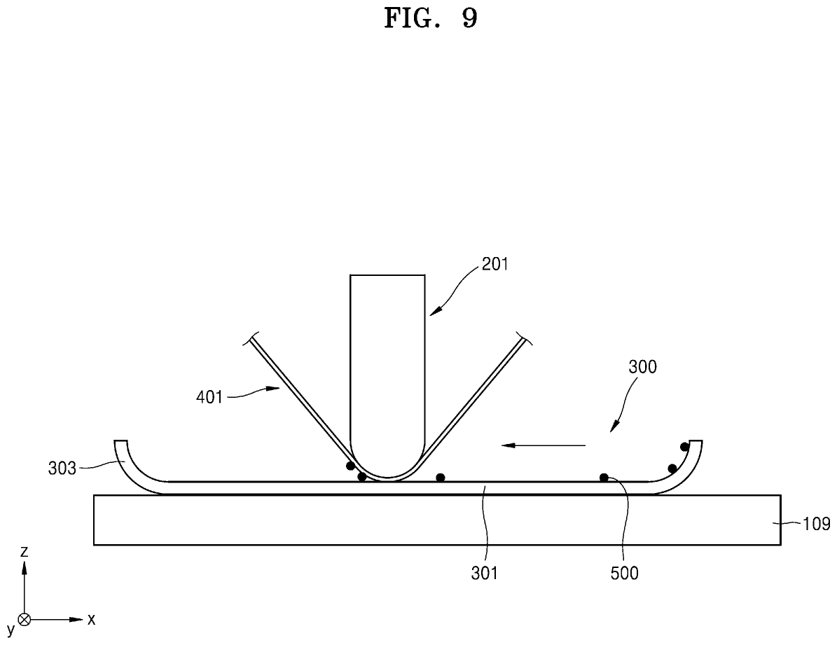

Referring to FIG. 9, the surface of the cover window 300 may be cleaned using the microfiber 401. More particularly, foreign materials on the surface of the cover window 300 may be removed using the microfiber 401.

FIG. 9 is a schematic cross-sectional view of the cleaning of the surface of the cover window 300 using the microfiber 401. In an embodiment, the stage 109 on which the cover window 300 is disposed may move in the first direction (e.g., the x direction or −x direction) to allow the microfiber 401 to clean the surface of the center area 301 of the cover window 300. The surface of the cover window 300 may be cleaned as the microfiber 401 passes the surface of the cover window 300 moving in the first direction (e.g., the x direction or −x direction) by the stage 109. As the cover window 300 moves in the first direction (e.g., the x direction or −x direction), the foreign materials 500 on the cover window 300 may contact the microfiber 401 and then be removed.

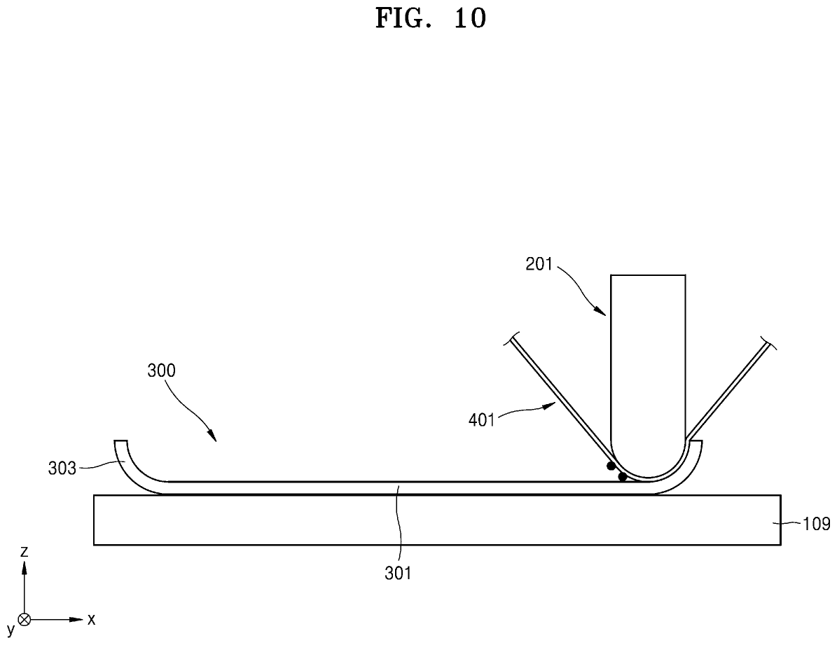

Referring to FIG. 10, when the cover window 300 moves in the first area 303 (e.g., the x direction or −x direction), the first portion 205 (see FIG. 7) of the pad 201 may contact (or match) another first area 303 of the cover window 300 with the microfiber 401 therebetween. In an embodiment, as described above, the third curvature of the first portion 205 (see FIG. 7) of the pad 201 and the first curvature of the first area 303 of the cover window 300 may be identical to each other. In such an embodiment, the third radius of curvature of the first portion 205 (see FIG. 7) of the pad 201 and the first radius of curvature R1 of the first area 303 of the cover window 300 may be identical to each other.

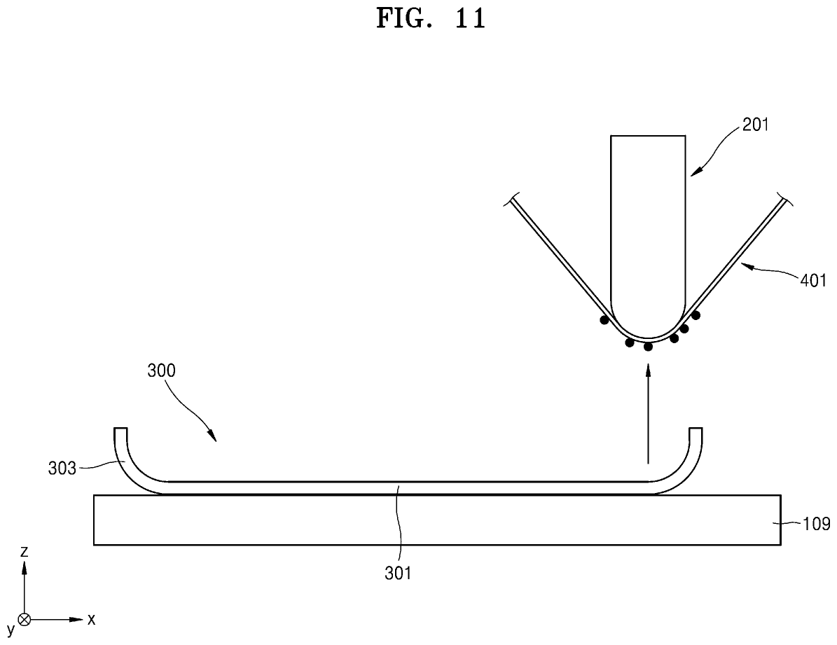

Referring to FIG. 11, the microfiber 401 which had finished the cleaning of the surface of the cover window 300 and the pad 201 being in contact with the microfiber 401 may be lifted by the pushing driver 108. After cleaning of the surface of the cover window 300, the pad 201 and the microfiber 401 being in contact with the pad 201 may be moved upward (e.g., the z direction) by the pushing driver 108.

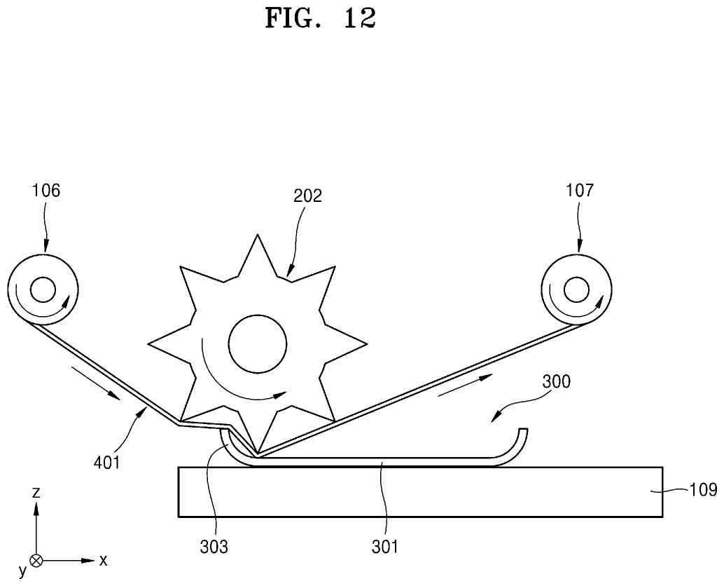

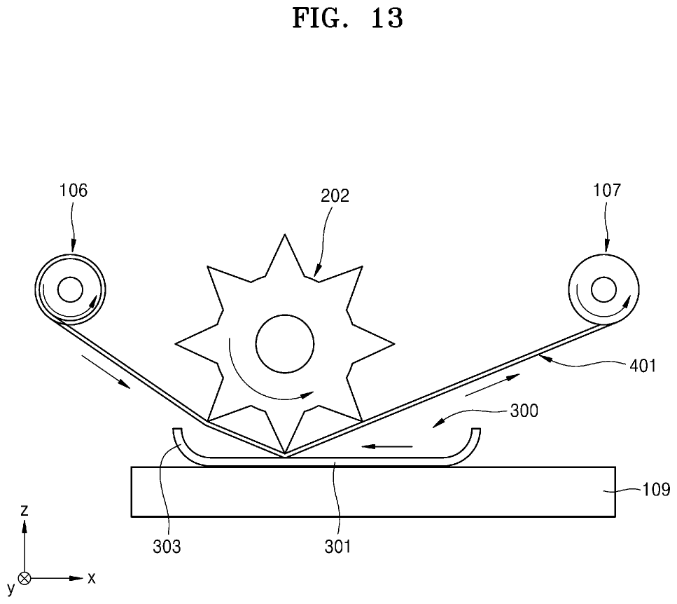

FIGS. 12 and 13 are schematic cross-sectional views showing a method of cleaning the cover window 300 according to an embodiment. More particularly, FIGS. 12 and 13 are schematic cross-sectional views of cleaning the surface of the cover window 300 by using the cleaning device of the cover window 300 including the pad 202 shown in FIGS. 4A to 4C.

Referring to FIGS. 12 and 13, the method may include: placing the cover window 300 on the stage 109, where the cover window 300 includes the center area 301, the first area 303 extending in the first direction (e.g., the x direction or − direction) from the center area 301 and having the first curvature, and the second area 302 extending in the second direction (e.g., the y direction or −y direction) crossing the first direction (e.g., the x direction or −x direction) from the center area 301 and having the second curvature; bringing the microfiber 401 into contact with the pad 202 having a sawtooth shape; bringing the microfiber 401 into contact with the surface of the cover window 300 by moving the pad 202 toward the cover window 300; and cleaning the surface of the cover window 300 by using the microfiber 401.

Referring to FIG. 12, the cover window 300 may be on the stage 109, where the cover window 300 includes the center area 301, the first area 303 extending in the first direction (e.g., the x direction or −x direction) from the center area 301 and having the first curvature, and the second area 302 (see FIG. 2A) extending in the second direction (e.g., the y direction or −y direction) crossing the first direction (e.g., the x direction or −x direction) from the center area 301, the microfiber 401 may be brought into contact with the pad 202 having the sawtooth shape, and the microfiber 401 may be brought into contact with the surface of the cover window 300 by moving the pad 202 toward the cover window 300.

The bent portion 207 (see FIG. 4A) of the pad 202 having the sawteeth shape may match (or contact) the second area 302 (see FIG. 2A) of the cover window 300 with the microfiber 401 therebetween. The fifth curvature of the bent portion 207 (see FIG. 4A) of the pad 202 having the sawtooth shape may be identical to the second curvature of the second area 302 (see FIG. 2A) of the cover window 300. In other words, the fifth radius of curvature R5 of the bent portion 207 (see FIG. 4A) of the pad 202 having the sawtooth shape and the second radius of curvature R2 of the cover window 300 may be identical to each other. As the bent portion 207 (see FIG. 4A) of the pad 202 having the sawteeth shape matches (or contacts) the second area 302 (see FIG. 2A) of the cover window 300 with the microfiber 401 therebetween, detergency on the surface of the cover window 300 may be improved.

After the pad 202 having the sawtooth shape contacts the first area 303 of the cover window 300 with the microfiber 401 therebetween, the microfiber 401 may be moved. A direction in which the microfiber 401 moves may be opposite to the direction in which the stage 109 moves. The pad 202 having the sawtooth shape may rotate by the microfiber 401 being moved. As the pad 202 rotates half a round, the first area 303 of the cover window 300 may be cleaned. Due to the rotation of the pad 202, the first area 303 of the cover window 300 and the microfiber 401 attached to the sawteeth of the pad 202 contact each other several times, and therefore, the detergency in the first area 303 of the cover window 300 may be improved.

Referring to FIG. 13, after the microfiber 401 contacts the surface of the cover window 300, the surface of the cover window 300 may be cleaned using the microfiber 401. After the pad 202 rotates half a round by the movement of the microfiber 401, the microfiber 401 may be paused. When the microfiber 401 is paused, the cover window 300 may be moved in the first direction (e.g., the x direction or −x direction) by the stage 109. The microfiber 401 contacting the pad 202 and the surface of the center area 301 of the cover window 300 may contact each other by the cover window 300 moved in the first direction (e.g., the x direction or −x direction) by the stage 109. As the microfiber 401 contacts the surface of the cover window 300, foreign materials on the surface of the cover window 300 may contact the microfiber 401, and therefore, the cover window 300 may be cleaned.

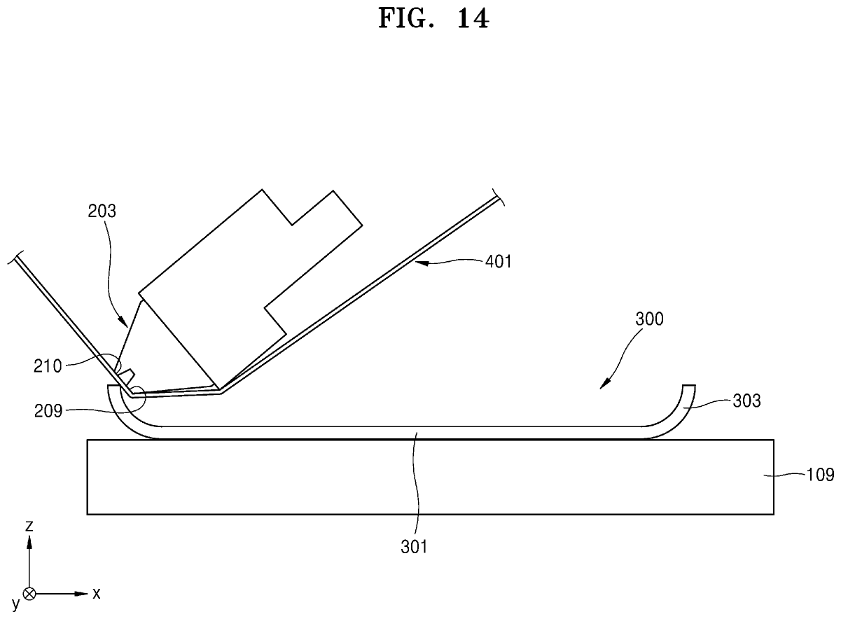

FIGS. 14 to 16 are cross-sectional views showing a method of cleaning the cover window 300 according to an embodiment. More particularly, FIGS. 14 to 16 are schematic cross-sectional views showing a method of cleaning the cover window 300 by using the cleaning device of the cover window 300 including the pad 202 shown in FIGS. 6A and 6B.

Referring to FIGS. 14 to 16, the method may include: placing the cover window 300 on the stage 109, where the cover window 300 includes the center area 301, the first area 303 extending in the first direction (e.g., the x direction or −x direction) from the center area 301 and having the first curvature, and the second area 302 (see FIG. 2A) extending in the second direction (e.g., the y direction or −y direction) crossing the first direction (e.g., the x direction or −x direction) from the center area 301; bringing the microfiber 401 into contact with the pad 203; bringing the microfiber 401 into contact with the surface of the cover window 300 by moving down the pad 203 toward the cover window 300; and cleaning the surface of the cover window 300 by using the microfiber 401.

In an embodiment, an angle of the pad 203 may be adjusted. The angle of the pad 203 may tilt in the −x direction (or the x direction) with reference to the third direction (e.g., the z direction or −z direction). As an angle between the pad 203 and the reference axis in the third direction (e.g., the z direction or −z direction) is adjusted, an adhesion between the microfiber 401 and the first area 303 of the cover window 300, in the first area 303 of the cover window 300, may be improved. As the angle between the pad 203 and the reference axis in the third direction (e.g., the z direction or −z direction) is adjusted, the detergency in the first area 303 of the cover window 300 may be improved.

As the pad 203 tilts in the −x direction (or the x direction) having the third direction (e.g., the z direction or −z direction) as the reference axis, the third portion 209 of the pad 203 may primarily contact the first area 303 of the cover window 300 with the microfiber 401 between. Next, as the angle between the pad 203 and the reference axis in the third direction (e.g., the z direction or −z direction) decreases, the fourth portion 210 of the pad 203 and the first area 303 of the cover window 300 may secondarily contact each other with the microfiber 401 therebetween. As the first area 303 of the cover window 300 may be cleaned twice by the microfiber 401 contacting the third portion 209 and fourth portion 210 of the pad 203, the detergency on the surface of the cover window 300 may be improved.

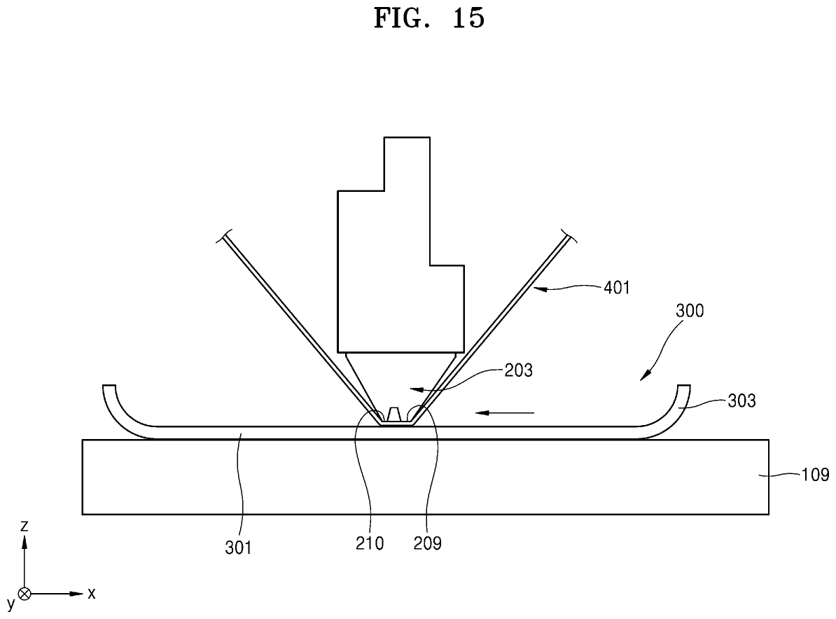

Referring to FIG. 15, while the microfiber 401 brought in contact with the pad 203 cleans the first area 303 of the cover window 300, the angle between the pad 203 and the reference axis in the third direction (e.g., the z direction or −z direction) decreases, and accordingly, the pad 203 may be placed in the third direction (e.g., the z direction or −z direction), that is, a direction perpendicular to the first direction (e.g., the x direction or −x direction). After the pad 203 is oriented in the third direction (e.g., the z direction or −z direction), the cover window 300 may be moved in the first direction (e.g., the x direction or −x direction) by the stage 109. As the cover window 300 is moved by the stage 109, the microfiber 401 being in contact with the pad 203 may contact the surface of the center area 301 of the cover window 300. As the cover window 300 is moved by the stage 109, the microfiber 401 being in contact with the pad 203 may clean the surface of the cover window 300. As the surface of the center area 301 of the cover window 300 may be cleaned twice by the microfiber 401 being in contact with the third portion 209 and fourth portion 210 of the pad 203, the detergency on the surface of the cover window 300 may be improved.

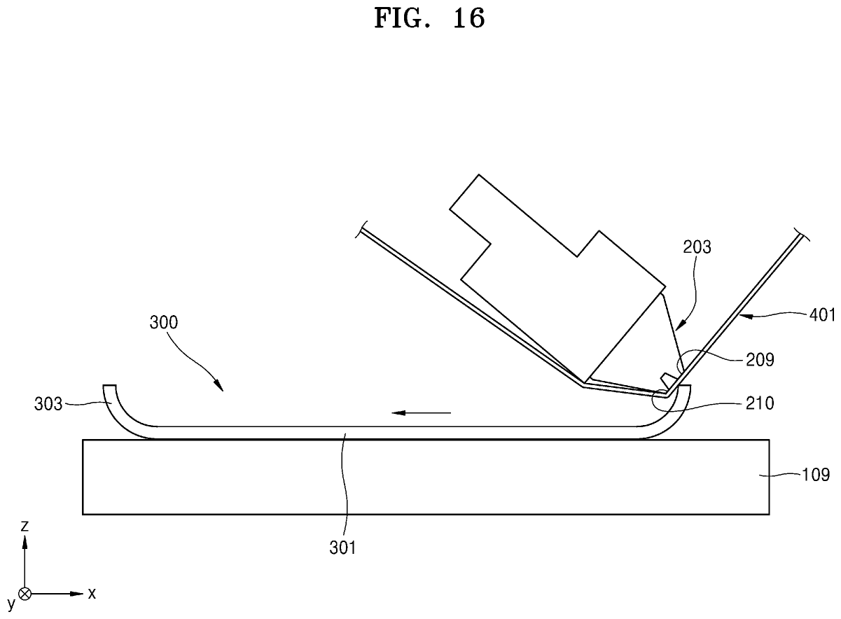

Referring to FIG. 16, after the center area 301 of the cover window 300 is cleaned, the degree of the pad 203 may be changed as the pad 203 moves in the x direction (or the −x direction) with reference to the third direction (e.g., the z direction or −z direction). As the degree between the pad 203 and the reference axis in the third direction (e.g., the z direction or −z direction) gradually increase, the third portion 209 of the pad 203 may primarily contact the first area 303 of the cover window 300 with the microfiber 401 therebetween. As the degree between the pad 203 and the reference axis in the third direction (e.g., the z direction or −z direction) gradually increases, the fourth portion 210 of the pad 203 may secondarily contact the first area 303 of the cover window 300 with the microfiber 401 therebetween. As the first area 303 of the cover window 300 may be cleaned twice by the microfiber 401 contacting the third portion 209 and fourth portion 210 of the pad 203, the detergency on the surface of the cover window 300 may be improved.

In devices for cleaning cover windows in the related art, curve portions of cover windows are not properly cleaned. In an embodiment of the invention, a contact force between the microfiber brought into contact with the pad and the surface of the cover window may be improved by adjusting a shape, a material, an angle, and rotation of the pad with which the microfiber is brought into contact, and accordingly, the bent areas of the cover window may be cleaned, and a cleaning time may be reduced.

According to the embodiments described above, an apparatus and a method of manufacturing the display device may be implemented, the apparatus and method by which the detergency in the bent areas of the cover window may be improved and the cleaning time may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a stage; and
a pad comprising a first portion,
wherein the first portion has a curvature identical to a first curvature of a first area of a cover window of the display device extending in a first direction from a center area of the cover window.

2. The apparatus of claim 1,
wherein the pad further comprises a second portion, and
the second portion has a curvature identical to a second curvature of a second area of the cover window extending in a second direction crossing with the first direction from the center area of the cover window.

3. The apparatus of claim 2, wherein the pad has a first width in the first direction and a second width in the second direction.

4. The apparatus of claim 3, wherein the first width is twice a radius of curvature of the first curvature of the first area of the cover window.

5. The apparatus of claim 4, wherein
the cover window has a first length in the second direction, and
the second width is identical to the first length.

6. The apparatus of claim 2, wherein the first curvature and the second curvature are different from each other.

7. The apparatus of claim 1, further comprising:
a pushing driver which moves the pad toward the cover window disposed on the stage.

8. The apparatus of claim 7, further comprising:
a microfiber between the pad and the stage.

9. An apparatus for manufacturing a display device, the apparatus comprising:
a stage;
a pad comprising a plurality of sawteeth arranged at a same interval toward outside a cylinder-shaped main body having an axis hole; and
and an axis which rotates the pad.

10. The apparatus of claim 9,
wherein, on a cross-section of the pad in a first direction, a length of the sawteeth is greater than a radius of curvature of a first curvature of a first area of a cover window of the display device extending in a first direction from a center area of the cover window.

11. The apparatus of claim 9,
wherein the axis is inserted into an axis hole of the pad, and
each of the axis hole and the axis has a rectangular parallelepiped shape.

12. The apparatus of claim 10,
wherein the sawtooth comprises a third portion having a same curvature as a second curvature of a second area of the cover window extending in a second direction crossing the first direction from the center area of the cover window.

13. A method of manufacturing a display device, the method comprising:
placing a cover window of the display device on a stage, wherein the cover window comprises a center area, a first area extending in a first direction from the center area and having a first curvature, and a second area extending in a second direction crossing the first direction from the center area and having a second curvature;
bringing a pad and a microfiber into contact with each other;
bringing the microfiber into contact with a surface of the cover window by moving down the pad toward the cover window; and
cleaning the surface of the cover window using the microfiber.

14. The method of claim 13, further comprising:
before the bringing the pad and the microfiber into contact, spraying ethanol to the microfiber.

15. The method of claim 13, wherein the pad comprises a first portion having a curvature identical to the first curvature.

16. The method of claim 15, wherein the pad further comprises a second portion having a curvature identical to the second curvature.

17. The method of claim 16, wherein a width of the pad in the first direction is twice a radius of curvature of the first curvature of the cover window.

18. The method of claim 17, wherein a width of the pad in the second direction is identical to a length of the cover window in the second direction.

19. The method of claim 14,
wherein the cleaning the surface of the cover window using the microfiber comprises moving the stage in a first direction.

20. The method of claim 15,
in the bringing the microfiber into contact with the surface of the cover window by moving the pad downward to the cover window, the first portion and the first area contact each other with the microfiber therebetween.
